(19) United States
(12) Patent Application Publication
(10) Pub. No.: US 2010/0188385 A1
(43) Pub. Date: Jul. 29, 2010

(54) SHIFT REGISTER CIRCUIT HAVING THRESHOLD VOLTAGE COMPENSATION

(75) Inventor: Evgueni Boiko, Horley (GB)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/669,070

(22) PCT Filed: Jul. 21, 2008
(86) PCT No.: PCT/IB2008/052915

§ 371 Date: Jan. 14, 2010

(30) Foreign Application Priority Data
Jul. 24, 2007 (EP) 07113022.3

(51) Int. Cl. G09G 5/00; G11C 19/18; G09G 3/36

(52) U.S. Cl. 345/211; 377/68; 345/87

(57) ABSTRACT

A shift register circuit comprises a plurality of stages, each stage being for providing an output signal to an output load and comprising a pull up transistor for pulling the output signal up to a high voltage rail and a pull down transistor for pulling the output signal down to a low voltage rail. Each stage comprises a circuit for sampling the threshold voltage of at least one of the pull up and pull down transistors and for adding the sampled threshold voltage to a control voltage offset, to provide a threshold-voltage-compensated signal for controlling the gate of the at least one of the pull up and pull down transistors. This provides threshold voltage sampling, in particular for the thin film transistor whose threshold voltage drift must be compensated (for example the pull-down thin film transistor).

### FIELD OF THE INVENTION

The invention relates to a shift register circuit, in particular for providing the row voltages to the display pixels of an active matrix display device.

### BACKGROUND OF THE INVENTION

Active matrix display devices comprise an array of pixels arranged in rows and columns, and each comprising at least one thin film drive transistor and a display element, for example a liquid crystal cell. Each row of pixels shares a row conductor, which connects to the gates of the thin film transistors of the pixels in the row. Each column of pixels shares a column conductor, to which pixel drive signals are provided. The signal on the row conductor determines whether the transistor is turned on or off, and when the transistor is turned on (by a high voltage pulse on the row conductor) a signal from the column conductor is allowed to pass on to an area of liquid crystal material, thereby altering the light transmission characteristics of the material.

The frame (field) period for active matrix display devices requires a row of pixels to be addressed in a short period of time, and this in turn imposes a requirement on the current driving capabilities of the transistor in order to charge or discharge the liquid crystal material to the desired voltage level. In order to meet these current requirements, the gate voltage supplied to the thin film transistor needs to fluctuate with significant voltage swings. In the case of amorphous silicon drive transistors, this voltage swing may be approximately 30 volts.

The requirement for large voltage swings in the row conductors requires the row driver circuitry to be implemented using high voltage components.

There has been much interest in integrating the components of the row driver circuit onto the same substrate as the substrate of the array of display pixels. One possibility is to use polycrystalline silicon for the pixel transistors, as this technology is more readily suitable for the high voltage circuit elements of the row driver circuitry. The cost advantages of producing the display array using amorphous silicon technology are then lost.

There is therefore an interest in providing driver circuits which can be implemented using amorphous silicon technology. The low mobility of amorphous silicon transistors, as well as the stress-induced change (drift) in threshold voltage, present serious difficulties in implementing driver circuits using amorphous silicon technology. The stress induced change is proportional in a non-linear manner to the voltage applied to a thin film transistor gate and to the duty cycle of this voltage.

In an active matrix display device, the pixel transistors are operated at low duty cycles, so that the drift is less of an issue than for the row driver circuit. It has been proposed to design the row driver circuits in a way which also uses transistors operated with low duty cycles, and these are known as “high impedance gate driver circuits”.

The row driver circuit is conventionally implemented as a shift register circuit, which operates to output a row voltage pulse on each row conductor in turn.

Essentially, each stage of the shift register circuit comprises a pull up transistor connected between a clocked high power line and the row conductor, and the pull-up transistor is turned on to couple the row conductor to the clocked high power line to generate a row address pulse. A pull-down transistor holds the voltage low for the remainder of the time. In order to ensure that the voltage on the row conductor reaches the power line voltage (despite the series-connected drive transistor), it is known to take advantage of a bootstrapping effect, using a stray capacitance of the output transistor. This is discussed in U.S. Pat. No. 6,052,426. These bootstrapping measures improve the performance of the circuit and improve the tolerance to variations in transistor characteristics. This in turn gives rise to an increased lifespan for the circuit.

Implementations of these circuits also use the outputs from previous rows as control signals for a given row, to control the timing of the bootstrapping effects.

There remains a problem with the known circuits that degradation of transistor performance, particularly for transistors that are operated with a high duty cycle and therefore normally on, limits the lifetime of the circuit.

### SUMMARY OF THE INVENTION

According to the invention, there is provided a shift register circuit comprising a plurality of stages, each stage being for providing an output signal to an output load and comprising a pull up transistor for pulling the output signal up to a high voltage rail and a pull down transistor for pulling the output signal down to a low voltage rail,

wherein each stage comprises a circuit for sampling the threshold voltage of at least one of the pull up and pull down transistors and for adding the sampled threshold voltage to a control voltage by capacitive coupling, to provide a threshold-voltage-compensated signal for controlling the gate of the at least one of the pull up and pull down transistors, wherein the circuit is adapted to apply a voltage step to the sampled threshold voltage for generating a turn-on signal, and is adapted to apply an opposite sign voltage step to the sampled threshold voltage, for generating a turn-off signal.

The invention provides threshold voltage (Vₜ) sampling, in particular for the thin film transistor whose threshold voltage drift must be compensated (for example the pull-down thin film transistor). This is used to generate a threshold-voltage compensated control voltage, and for each stage of the shift register circuit.

The sensing circuit can be operated with low duty cycle, for example in the time available during frame blanking The sampled threshold voltage can then be applied to any input drive signal to provide compensation for ageing.

The sampling circuit may comprise a sampling capacitor in series between a control voltage input for the stage and the gate of the at least one of the pull up and pull down transistors. In this way, a voltage provided on the capacitor will be added to the input voltage, and can thereby provide a compensation function.

The sampling circuit can comprise a first switch for coupling one side of the sampling capacitor to a low voltage rail and a second switch for coupling the other side of the sampling capacitor to a high voltage rail. This enables the capacitor to be charged to a maximum voltage, and it can then be discharged to store a sampled threshold voltage.

The sampling circuit can further comprise a charge pump circuit associated with the second switch, for boosting the high voltage rail voltage. This enables compensation of a wider range of threshold voltages, as the capacitor can be charged to a higher level, and thereby store a higher threshold voltage.

The sampling circuit may comprise a third switch for shorting the gate and drain of the at least one of the pull up and pull down transistors or for shorting the gate and drain of a transistor used to replicate the at least one of the pull up and pull down transistors. This puts the transistor being sampled into a diode configuration, and this can be used to discharge the capacitor voltage until the threshold voltage is reached, which corresponds to the diode-connected transistor forward bias voltage drop.

A capacitor can be connected between the control line for controlling the third switch and the other side of the sampling capacitor. The control line can then be used for introducing a step change to cause charge sharing and alter the charge stored on the storage capacitor.

The sampling circuit may comprise a fourth switch and a fifth switch connected in series between the power rails, with the junction between the fourth and fifth switches connected to one side of a capacitor, the other side of the capacitor being connected to the gate of the at least one of the pull up and pull down transistors. These additional switches can be used to store an additional compensation element on the capacitor. In particular, either a fixed positive voltage offset (to turn the thin film transistor on), or a fixed negative voltage offset (to turn the thin film transistor off) can be added to the sampled threshold voltage.

Instead of using a second capacitor to alter the sampled threshold voltage, the first switch can be connected between a reference power line and the one side of the sampling capacitor, such that the threshold voltage is sampled relative to the reference power line voltage. A further switch is connected between the one side of the sampling capacitor and a low voltage rail. This enables a change to the sampled threshold voltage by applying a step change to the input.

Leakage current control circuitry can also be provided for controlling the direction of flow or magnitude of leakage current to or from the gate of the at least one of the pull up and pull down transistors, connected between the gate of the at least one of the pull up and pull down transistors and a power supply line. This can be used to stabilize the stored threshold voltage over time, or ensure that the effect of the compensation is not reduced over time.

The leakage current control circuitry can comprise two transistors in series with connected gates and with a control voltage line to the series connection between the transistors. This control voltage line can set the operating point of the pair of transistors, so that (net) leakage currents can be controlled to flow in a desired direction.

The leakage current control circuitry may further comprises a third transistor with the gate and source terminals connected to the source and drain terminals of one of the two transistors. This introduces a threshold voltage, and can be used to ensure that the leakage current is as close to zero as possible.

The leakage current control circuitry may instead comprise a (single) transistor connected between the gate of the at least one of the pull up and pull down transistors and the power supply line, wherein the power supply line comprises a tri-state power source, and the leakage current control circuitry further comprises a control voltage line for controlling the voltage applied to the transistor when the power supply is switched to a high impedance state. This enables a single transistor to be used to control the leakage current flow.

The circuit for sampling the threshold voltage of at least one of the pull up and pull down transistors may include the at least one of the pull up and pull down transistors, so that there is sampling of the actual transistor. However, the circuit for sampling the threshold voltage of at least one of the pull up and pull down transistors may include a transistor used to replicate the behavior of the at least one of the pull up and pull down transistors. this replica transistor can for example be operated at the same duty cycle and with the same voltages.

Each stage preferably comprises an input section and an output section, wherein the output section comprises the pull-up and pull-down transistors, and a bootstrap capacitor between the gate of the pull up transistor and the output. The input section of each stage can comprise a first input section input (row n−1) connected to the output of the input section of a preceding stage; and a transistor for charging the first bootstrap capacitor and controlled by the first input (row n−1).

The invention is particularly suitable for implementation using amorphous silicon technology.

The invention also provides an active matrix display device (for example a liquid crystal display), comprising:

an array of active matrix display pixels;

row driver circuitry comprising a shift register circuit of the invention.

The invention also provides a method of generating multiple stage shift register circuit outputs for providing a signal to an output load, comprising, for each stage of the shift register circuit:

generating an output signal by switching on a pull up transistor to pull the output signal up to a high voltage rail or switching on a pull down transistor to pull the output

signal down to a low voltage rail,

wherein the method further comprises:

sampling the threshold voltage of at least one of the pull up and pull down transistors;

applying a voltage of a first polarity to the sampled threshold voltage for generating a turn-on signal for controlling the gate of the at least one of the pull up and pull down transistors; and

applying a voltage of an opposite second polarity to the sampled threshold voltage, for generating a turn-off signal for controlling the gate of the at least one of the pull up and pull down transistors.

### BRIEF DESCRIPTION OF THE DRAWINGS

Examples of the invention will now be described in detail with reference to the accompanying drawings, in which:

FIG. 1 shows a first simplified example of circuit of the invention to illustrate the principles of the invention;

FIG. 2 shows a first example of circuit of the invention in more detail;

FIG. 3 shows a second example of circuit of the invention in more detail;

FIG. 4 shows the circuit of FIG. 3 showing the transistor implementation of the switches;

FIG. 5 shows examples of timings for the operation of the circuit of FIG. 4;

FIG. 6 shows a third example of circuit of the invention;

FIG. 7 shows examples of timings for the operation of the circuit of FIG. 6;

FIG. 8 shows a fourth example of circuit of the invention;

FIG. 9 shows a firth example of circuit of the invention;

FIG. 10 shows the circuit of FIG. 9 showing the transistor implementation of the switches;

FIG. 11 is used to show leakage currents in the circuits of the invention;

FIG. 12 shows a first example of circuit which controls the leakage currents;

FIG. 13 shows a second example of circuit which controls the leakage currents;

FIG. 14 shows a third example of circuit which controls the leakage currents;

FIG. 15 shows a fourth example of circuit which controls the leakage currents; and

FIG. 16 shows how a charge pump can extend the range of threshold voltage compensation possible;

FIG. 17 shows a fifth example of circuit of the invention;

FIG. 18 shows a timing diagram for the circuit of FIG. 17; and

FIG. 19 shows how the circuit blocks of FIG. 17 are connected together.

It should be noted that these figures are diagrammatic and not drawn to scale. For the sake of clarity and convenience, relative dimensions and proportions of parts of these figures have been shown exaggerated or reduced in size.

### DETAILED DESCRIPTION OF THE EMBODIMENTS

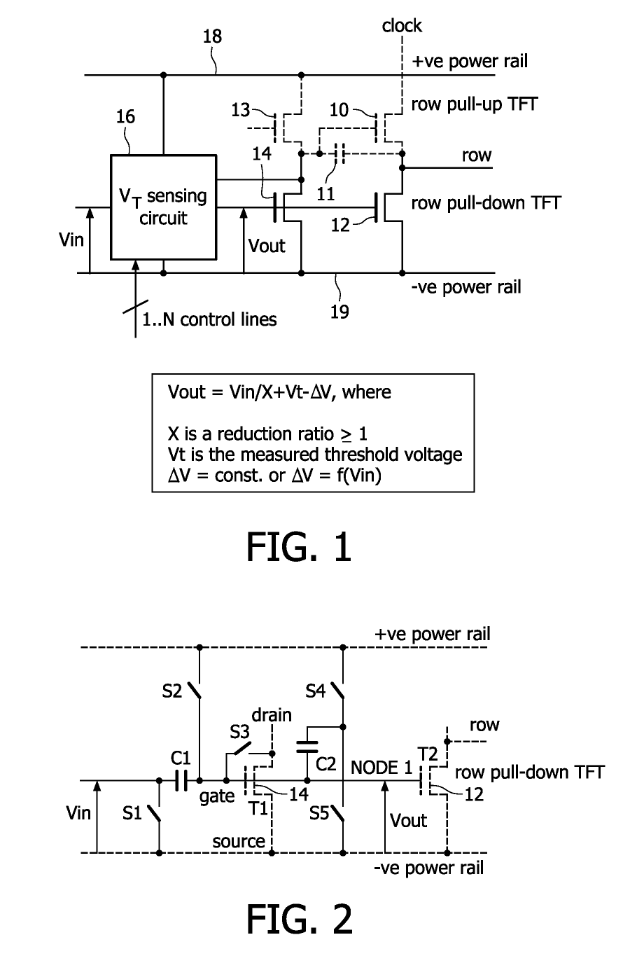

FIG. 1 shows a first simplified example of circuit of the invention to illustrate the principles of the invention.

The invention provides sensing of the threshold voltage of the most critical transistor or transistors in the circuit. The row driver circuit has a row pull-up transistor 10, which is turned on to provide a row pulse on the row from a clocked power supply line “clock”, and a row pull-down transistor 12 for holding the row at a low negative power rail voltage for the remainder of the time. The row pull-down transistor 12 is operated with a high duty cycle and therefore suffers greatest drift.

In one example, the invention provides threshold voltage sensing of the row pull down transistor 12. The sensing circuit may use the thin film transistor (TFT) of the row driver circuit, or it may use a dedicated TFT which is designed to match the characteristics of the TFT being compensated.

FIG. 1 shows a transistor 14 used to replicate the conditions of the pull down transistor 12, and a threshold voltage sensing circuit 16 supplied with power from positive and negative voltage lines 18, 19.

As shown in FIG. 1, the sensing circuit 16 derives an output Vₒᵤₜ which generally can apply an attenuation X to the input voltage V_{in,} add a threshold compensation Vₜ and add or subtract an offset ΔV.

In the example of FIG. 1, the amount of threshold voltage drift will be identical for both the row pull-down TFT 12 and the TFT 14 on which the sensing is performed regardless of the TFT relative sizes and loading, because Vₜ drift is a function of the signal on the gate only.

FIG. 1 also shows a bootstrap capacitor 11 and a transistor 13 for charging the bootstrap capacitor, for example using a high signal from the previous stage.

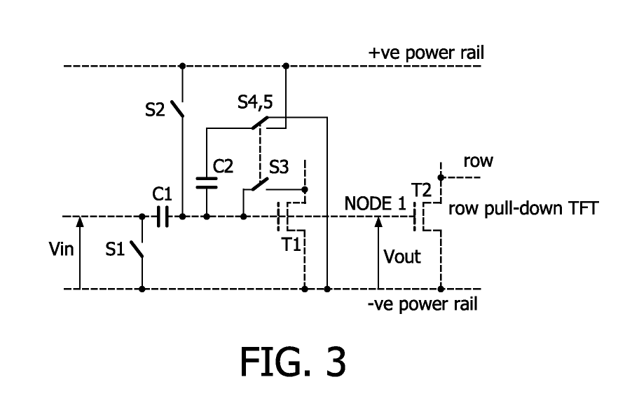

FIG. 2 is a schematic diagram illustrating the principle on which such a circuit can be based.

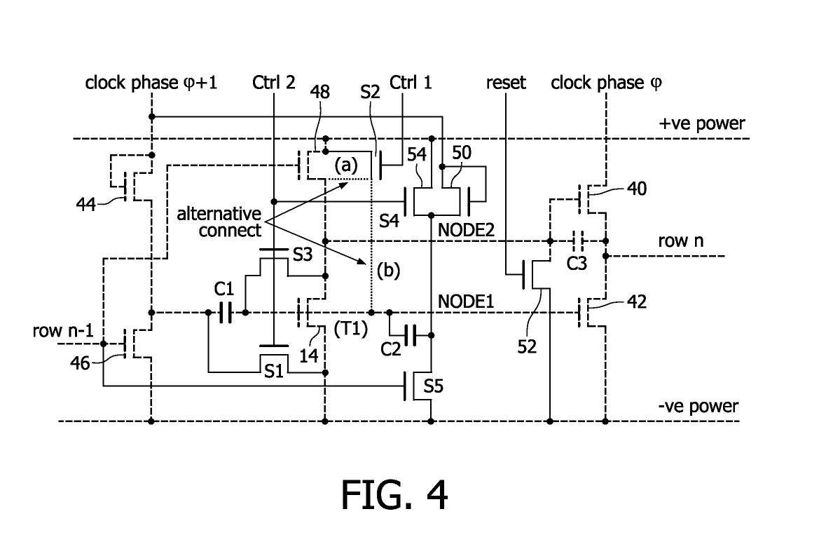

The circuit has a first switch 51 for holding one side of a sampling capacitor C1 to the fixed negative rail. Switch S2 allows the positive voltage rail to be loaded onto the gate of the transistor being sampled and onto the other side of the storage capacitor. The charging of the voltage on NODE1 can be direct (connection b shown in FIG. 4) or indirect via switch S3 (connection a shown in FIG. 4). The latter connection requires control lines Ctrl1 and Ctrl2 to overlap so that transistors 48 and S3 are on at the same time. Another option is for charging of the voltage on NODE1 via NODE2 and the transistor S3.

Switch S3 shorts the drain and gate of the replication transistor 14 so that the transistor is diode-connected. This enables the transistor gate to discharge to the threshold voltage, and this can be stored on the input capacitor C1. Switches S4 and S5 enable the stored voltage to be scaled or shifted.

The circuit can be operated in the following way:

### Time Interval 1:

Switches S1, S2 and S4 are closed and switches S3 and S5 are open. The voltage rail difference is stored on the capacitor and the gate of the transistor being sampled (NODE 1) is charged to a voltage above its threshold Vₜ.

### Time Interval 2:

Switches S1, S3 and S4 are closed and switches S2 and S5 are open. When switch S3 is closed, the transistor T1 is diode-connected and NODE1 is actively discharged via transistor 14 until the threshold voltage Vₜ is reached. Following this, NODE1 continues to discharge but very slowly due to sub-threshold leakage. Thus, the end result is that the threshold voltage is stored on NODE1, and there is a corresponding voltage across the capacitor C1, as one terminal is still connected to the negative rail.

### Time Interval 3:

Switches S1, S2, S3, S5 are open and switch S4 is closed. Vₜ is now sampled onto C1 with the input of the capacitor connected to the input voltage.

The voltage on the node Node1 is held by the capacitor C2, as the switch S4 has remained closed.

As this capacitor is in series with the input, it can act to provide a voltage step to any voltage applied to the input. In particular, this can bring the voltage applied to the gate of the pull down transistor to a level higher than the high voltage rail.

In the example above, it can be ensured that no DC path is established through transistor 14 by ensuring that the switch S2 is opened before S3 is closed. However the circuit may be operated with S3 closed for part or whole of the time interval during which S2 is closed. Indeed in this case, S2 may be connected between the positive supply rail and the drain terminal of T1 instead of the gate of transistor 14. Threshold voltage sensing could still be accomplished, for example so long as S2 is opened before S3 is opened, or if the function of S2 is implemented with a TFT that is much smaller than transistor 14.

### Time Interval 4:

In the following time period, NODE1 can be taken a fixed voltage ΔV below the threshold voltage Vₜ now stored on C1, by opening S4 and closing S5 whilst Vᵢₙ=0 V. This causes charge sharing between capacitors C1 and C2, and results in an output voltage Vₒᵤₜ=Vₜ−ΔV where ΔV is a constant fraction of the potential difference between positive and negative supply rails and is determined by the relative sizes of all capacitances in the system. Alternatively NODE1 can be raised above Vₜ by applying a positive voltage Vᵢₙ. This results in an output voltage Vₒᵤₜ=Vₜ+Vᵢₙ/X where X is defined by the relative sizes of capacitances C1, C2 and any parasitic capacitances of NODE1.

The scaling and offset enable a gate control voltage to be generated implementing the desired turn-on function, but with compensation for the threshold voltage.

The circuit thus operates to charge a maximum voltage rail voltage on the storage capacitor as a reset operation. The transistor gate is charged and then discharged until the threshold voltage Vₜ is reached, and this is sampled on the capacitor. An additional voltage is then also provided to the gate of the transistor being controlled, so that the end result is a threshold-voltage-compensated gate voltage. A fixed voltage difference may be provided above or below the threshold voltage, to provide constant drive conditions for the transistor being controlled, and enabling it to be driven on or off.

Thus, the circuit can be used to provide compensation for threshold voltage for a gate signal which is for turning the pull-down-transistor on, which is the majority of the time, namely when the row output is low. It can also provide a voltage step below the measured threshold for times when the pull-down transistor is to be turned off, namely in preparation for and during the row output pulse.

For turning the pull-down transistor on, the sampling capacitor provides a step voltage change to the conventional control voltage applied to the gate to provide threshold voltage sampling. In the circuit shown, NODE1 is kept charged by the clock phase φ+1, which periodically recharges the NODE1 voltage, through the capacitor C1.

A variation on the above principle is explained with reference to FIG. 3. The switches S1 to S5 perform the same functions, but in this case the switches S3, S4 and S5 are not independent. On completion of the threshold voltage measurement phase, NODE1 is automatically taken a fixed voltage below Vₜ by the combined switch S4,5, again defined by the relative sizes of all capacitances in the system.

FIG. 4 is a first circuit diagram to show how a practical circuit can be made based on the basic principle discussed above.

The lighter part of the circuit represents a known stage of a multi-phase dynamic logic shift register.

The known shift register circuit has a pull-up transistor 40 and a pull down transistor 42 as the output stage. An input stage has a diode connected transistor 44 connected to the clock phase signal for the next row, and two transistors 46,48 which are controlled by the previous row driver signal. These function to prime the circuit in advance of the row pulse generation. In particular, a bootstrapping capacitor C3 is charged in the previous row period through transistor 48, whereas the input is held low by transistor 46.

The dashed circuit in FIG. 4 is well known to those skilled in the art, and implemented a bootstrapping function and a reset function based on signals from the preceding and following stages of the shift register circuit.

The known circuit has an idling state in which NODE 1 is charged up and the output is held low. Until the previous row is pulsed, the circuit remains in this state, and the clock phase signals do not result in any change in the output. The voltage on NODE1 needs to be above the threshold voltage of the pull-down transistor during this state.

When the previous row fires (or when a start pulse is introduced for the first row), transistors 46 and 48 are turned on, NODE2 is charged up, the bootstrapping capacitor C3 is charged, and transistor 40 is turned on. The voltage on NODE1 need to be brought below the threshold voltage of the pull-down transistor in preparation for the driving of the row with a high pulse.

In the next clock phase pulse (φ), the row output follows the clock phase, and the gate voltage of the pull-up transistor is pushed up above the positive rail by the bootstrapping capacitor, which ensures that transistor 40 is turned hard on.

During the subsequent clock phase, the transistor 42 is turned on again.

The bold components in FIG. 4 implement the switches of FIG. 2. The transistors are labeled as switches S1 to S5, corresponding to those in FIG. 2.

In addition to transistors implementing the functions of the switches in FIG. 2, there is a diode-connected transistor 50 between the next clock phase and the node at the gate of the transistor being tested (NODE1). This ensures that the drain of the transistor S5 is maintained high during normal operation, so that when it is discharged to the negative power rail on arrival of the previous row pulse (row n−1), this has the effect of pulling down the voltage on NODE1 below the threshold voltage in preparation for the clock phase during which the row is fired.

Thus, the circuit operates to pull the voltage of NODE1 below the threshold voltage of transistor 42 before transistor 40 is turned on, as well as increasing the gate voltage of transistor 42 when it is to be turned on.

A reset transistor 52 is also shown for resetting the bootstrapping capacitor C3 immediately after the sampling operation, in order to prevent spurious firing of rows when the main shift register clocks become active. It provides a direct way of resetting NODE2. An alternative is to connect the transistor 52 in parallel with transistor 44.

One control line Ctrl1 controls only switch S2 (transistor 52) and thereby controls the charging of the transistor 14 to above its threshold. Two possible connection paths for the source of this transistor are shown as (a) and (b). A second control lone Ctrl2 controls switches S1, S3 and S4 and thereby controls the threshold voltage sampling. The switch S5 is controlled by the previous row pulse.

The circuit in FIG. 4 is operated in the following way.

Control clocks Ctrl1, Ctrl2 are put high for two respective time intervals t1, t2. It is does not matter whether t1 or t2 begins first, or whether they overlap. The following conditions apply:
a) time interval t1 with the high Ctrl1 clock must be sufficiently long to allow NODE1 to reach Vₜ or above, via switch S2, at least before the end of the time interval t2;
b) after time interval t1 is over, time interval t2 must extend long enough to provide sufficient time for NODE1 to settle approximately to Vₜ, with S2 open. In the case when time intervals t1, t2 do not overlap, or overlap for a very short time, C3 must be sufficiently large in order to charge NODE1 to Vₜ or above at the start of time interval t2.

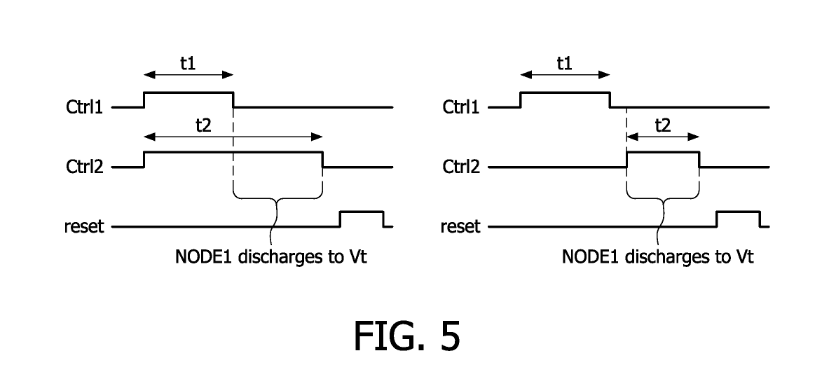

Two possible timing diagrams are shown in FIG. 5.

Once the threshold voltage sensing sequence described above has been performed, the shift register stage can be operated normally—a high signal from row n−1 will pull NODE1 below Vₜ and simultaneously charge NODE2 (i.e. charge the bootstrapping capacitor) ready for firing the row output when the awaited clock phase φ arrives.

The stage is reset by the next clock phase φ+1.

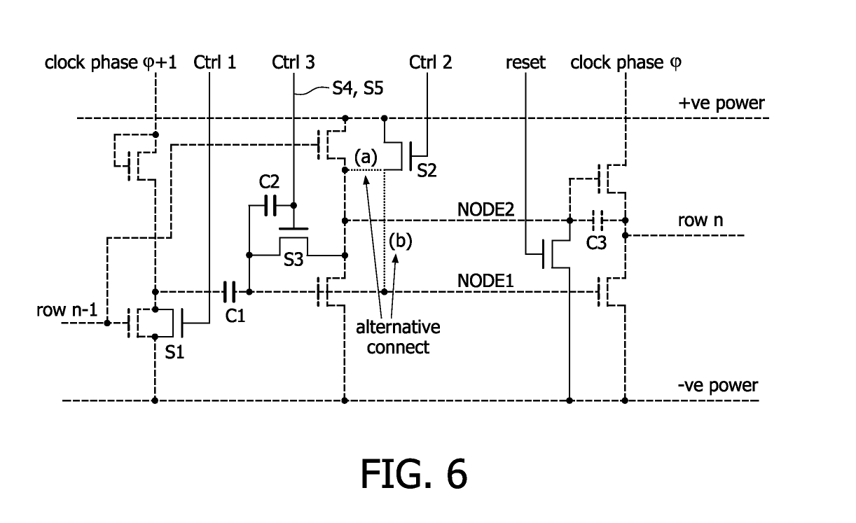

FIG. 6 shows an implementation based on the circuit of FIG. 3. The dashed components are identical to FIG. 5.

The transistors are again labeled with switch names. The switches S4 and S5 in the previous circuits select one of the voltage rails, and in the circuit of FIG. 6, this is implemented by the control line Ctrl3. Thus, control line Ctrl3 switches between the voltage rails in operation of the circuit.

The first control line Ctrl1 controls the switch S1, and the second control line Ctrl2 controls the switch S2.

The circuit shown in FIG. 6 operates as follows.

Control clocks Ctrl1, Ctrl2, Ctrl3 are put high for time intervals t1, t2, t3 respectively. Again, it is not critical in what order these control clocks are switched to high level. The following conditions must be satisfied:
a) t1 must begin a sufficient1y long time before t2 ends, in order to allow NODE1 to reach Vₜ or above during the time interval t3;
b) t1 and t3 must substantially overlap;
c) the time period when t2 is over and t1, t3 are not yet over must be sufficiently long to allow NODE1 to discharge to Vₜ (approx.).

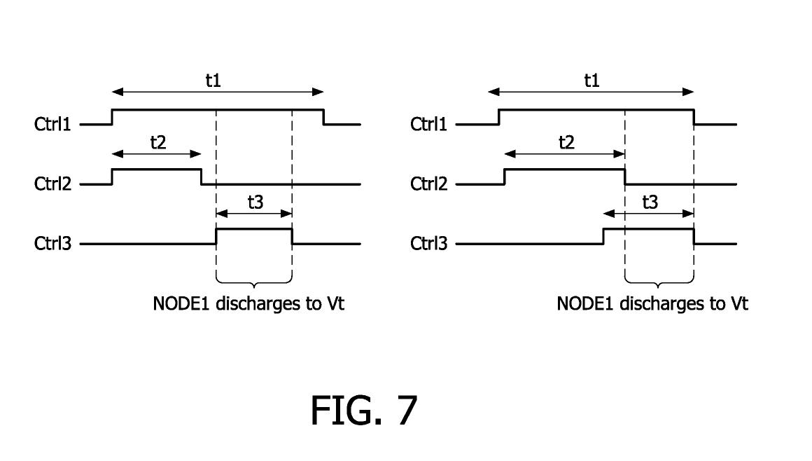

Two possible timing diagrams are shown in FIG. 7.

The threshold voltage sensing sequence as described above for the general circuit principle and for the detailed embodiments can be performed for all stages of the shift register at once (e.g. during frame blanking), either every frame or every Nth frame. Alternatively it can be performed in a time-staggered fashion for groups of shift register stages (e.g. grouping may be done according to which phase of a multi-phase clock signal is used to clock the output of the stages).

The sensing function can alternatively be performed once per frame sequentially for each stage of the shift register, e.g. using outputs from previous stages as control signals Ctrl1, Ctrl2.

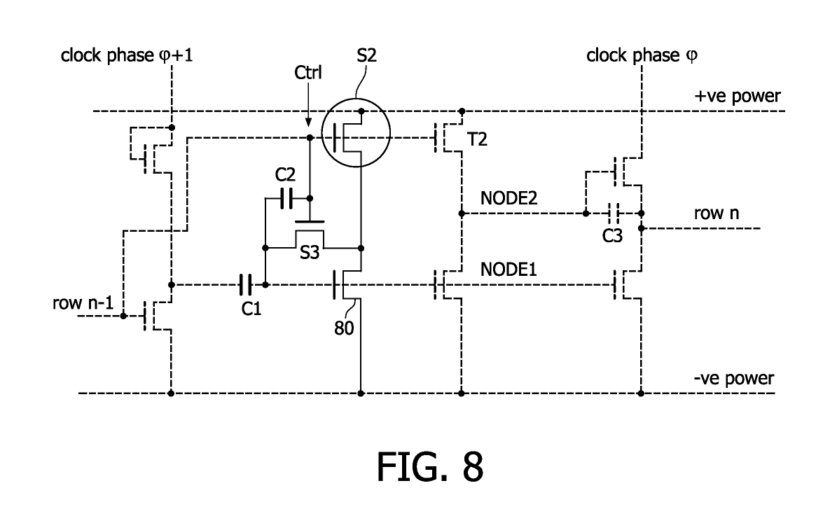

FIG. 8 shows a further embodiment where the threshold voltage measurement phase is combined with the shift register pre-selection phase (i.e. bootstrapping capacitor charging).

The advantage of this circuit is simplicity, in that only one control input is necessary for the threshold voltage sensing part, with the previous shift register stage output used as the control signal.

The circuit has a transistor S2 for charging NODE1 via the switch S3, as well as a pull-down transistor 80.

NODE1 is charged above the threshold voltage by some considerable margin and it is never discharged down to the threshold voltage as in the other circuit examples above. The margin can be reduced by making the lower TFT 80 bigger and the upper transistor S2 a minimum dimension TFT.

The result is that the voltage which NODE1 charges to will follow the threshold voltage of the larger transistor, which ages over time. This is not an exact sampling of the threshold voltage, but is sufficient for operation of the circuit. The term “sampling a threshold voltage” should be construed accordingly, as covering the generation of a voltage which is dependent on the threshold voltage. Additionally some sort of feedback circuit could be added to reduce this margin, however in any case with appropriate choice of the capacitance of C2, the potential on NODE1 can be kicked below Vₜ when “row n−1” goes low again, even if the starting potential is somewhat higher than the threshold voltage.

The transistor T1 holds the left side of the sampling capacitor C1 at the negative rail while row n−1 is high. When row n−1 goes low, the left side of the capacitor C1 is no longer held to the negative. However when the voltage dips below the negative voltage rail by more than the threshold voltage of transistor T1, then transistor T1 begins to conduct again. Thus, the left side of C1 is eventually returned close enough to the negative rail.

Only 3 clocks are sufficient to operate the shift register (2 with additional modifications). When row n−1 is high, NODE2 is pre-charged to charge the bootstrap capacitor in the usual way. The transistor T3 is biased with a voltage roughly equal to the threshold voltage Vₜ and is therefore only weakly turned on.

When row n−1 returns to low, NODE1 is taken below Vₜ and NODE2 remains charged so ensuring that T4 is ready for firing when clock phase φ arrives.

The drawback of this circuit is that DC paths are created which results in increased power consumption.

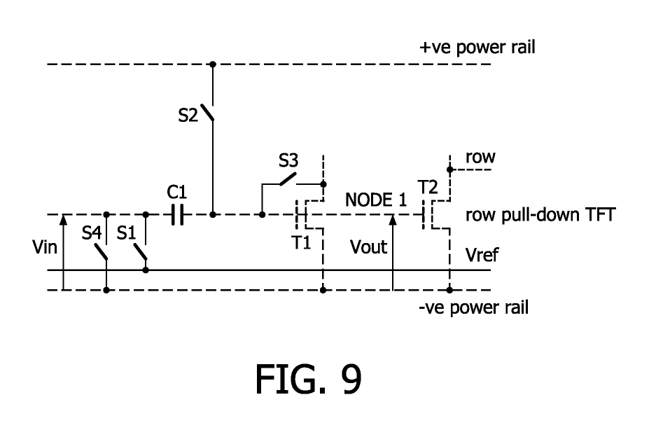

FIG. 9 shows a further embodiment which allows operation without the capacitor C2, used in the previous examples for providing a voltage step to the sampled threshold voltage.

As shown, compared to the circuit of FIG. 2, the capacitor divider arrangement of switches S4, S5 and the capacitor C2 is replaced by a third power rail that has a potential in between the negative and positive power rails, and the switch S1 for coupling this third power rail voltage to the input side of the sampling capacitor C1. In the same way as the examples above, switch S1 is used to hold the input side of the capacitor C1 to a low voltage during the threshold sampling, but this time the voltage is not the low voltage rail, but is a slightly higher reference voltage. The other components are the same as in FIG. 2.

During the first time interval, switches S2 and S1 are closed; and switches S4 and S3 are open. NODE 1 is thus charged to the potential of the positive power rail, and the input side of the capacitor is at the intermediate voltage V_{ref}.

During the second time interval, switches S3 and S1 are closed; and switches S4 are S2 open. This implements the threshold voltage sampling as in the previous examples.

During the third time interval 3, switches S4, S2, S3 are open and switch S1 open or closed. NODE1 is now at approximately the threshold voltage relative to the negative power rail.

There are of course variations to this sequence without compromising the intended end result of sampling the threshold voltage value onto the capacitive NODE1. For example, during the first time Interval the switch S1 could be closed and S4 open—thus increasing the voltage range available for threshold voltage measurement during the second time interval.

In the following time period NODE1 can be taken a fixed voltage below the threshold voltage by closing S4 (with S1 open), so that the input side of the capacitor C1 is stepped to a lower voltage.

This circuit can also be used to raise the potential of NODE1 to a fixed voltage above the threshold voltage by applying a positive voltage Vᵢₙ (with S1 and S4 open). The actual voltage Vₒᵤₜ on NODE1 is then Vₜ+Vᵢₙ/X where X is defined by the relative sizes of capacitor C1 and any parasitic capacitances of NODE1.

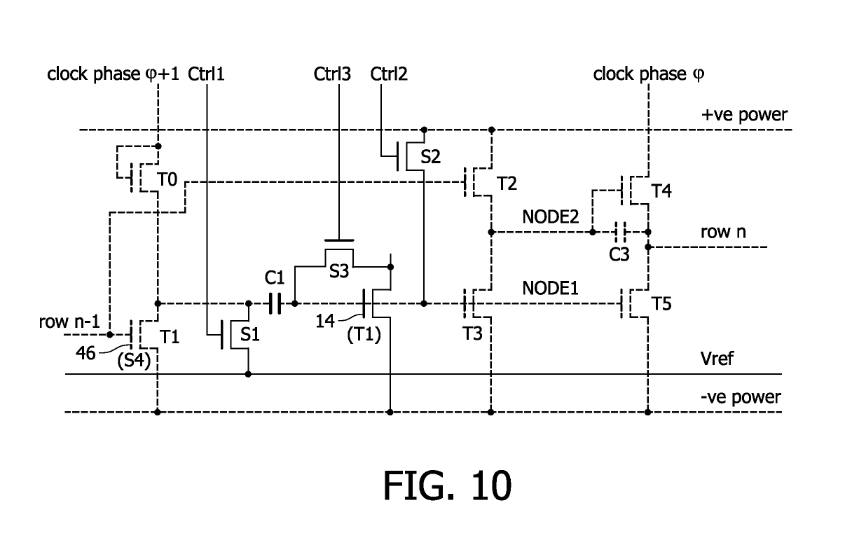

FIG. 10 shows a possible circuit implementation.

In this example the transistor 14 (T1) used to replicate the conditions of the pull down transistor is in addition to the transistor between NODE2 and the negative power rail, which forms part of the known row driver circuit. This enables independent design of the transistor used for threshold sampling. Furthermore, the transistor S4 for pulling the input side of the capacitor C1 to the negative voltage rail is implemented by the existing input transistor 46.

In the circuits above, as the transistors age and their threshold voltage Vₜ shifts upwards, a fixed voltage ΔV is added on top of Vₜ in order to keep the aging transistors turned on. Initially, the resulting voltage is in the range between the negative and positive power supply rails but at some point in the circuit life, this voltage ends up above both the negative and the positive supply rails. The operation of such a circuit requires an auxiliary isolating TFT (or TFTs) connected between the electric node onto which the threshold voltage is sampled and a DC level, typically the supply rails.

Since TFTs are not perfect switches, these auxiliary devices introduce undesirable leakage paths when they are turned off. The leakage current rises exponentially with drain-source voltage on the auxiliary TFT(s) and is also proportional to temperature. There may be conflicting requirements for the sizing of these TFTs. On the one hand they may be required to be large enough to provide adequate charging/discharging function in the available time and at the lowest operating temperature. On the other hand they need to be as small as possible to limit the amount of leakage through them at the highest operating temperature and/or voltage. Thus, increasing the total capacitance of the node in order to mitigate the effect of leakage from/into it does not help since the same TFTs that charge/discharge the node are also the ones that cause the leakage.

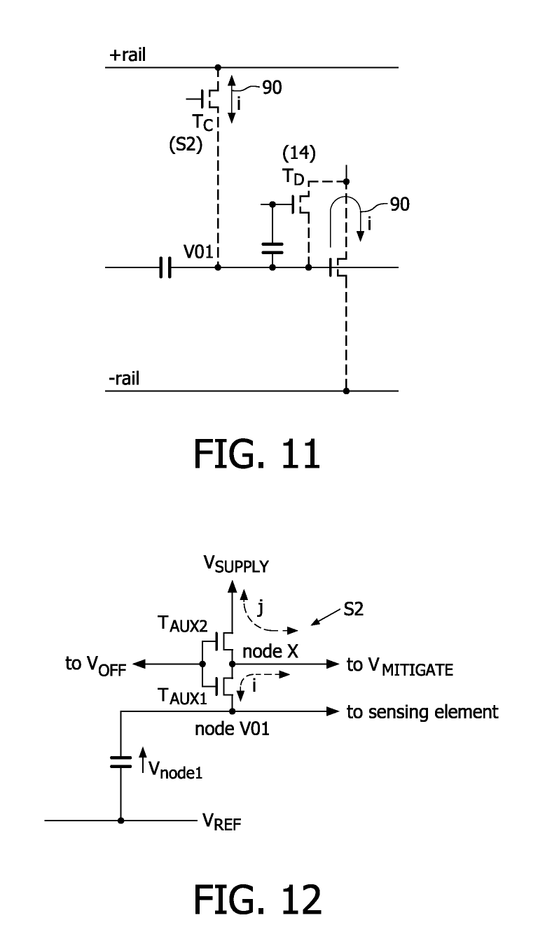

FIG. 11 is used to explain the leakage paths, in the off-state transistors. The leakage paths are shown as 90. Transistor TC is the transistor S2 for providing the high voltage rail voltage to the node, and the transistor TD represents the combination of transistors 14 and switch S3 which together provide a path to the low voltage rail.

One of the leakage paths is down toward the negative supply rail and the other one is up toward the positive supply rail. When the node voltage V01 is at some equilibrium potential between the positive and negative supply rail potentials (defined by the ratio of TC & TD dimensions) the leakage currents into/out of the node will exactly balance. When the node is below this equilibrium potential, the leakage will tend to gradually increase the node potential V01 toward the equilibrium point. When the node is at a potential above the equilibrium point the leakage will tend to discharge it back down toward it.

In this type of circuit, it is possible for the node potential to be “kicked up” above the positive supply rail in which case both leakage paths will tend to discharge node V01.

In the gate driver application, the threshold voltage sensing circuits can be operated either simultaneously for all gate driver stages, or sequentially immediately or shortly before each gate driver stage is fired, and the implications of leakage can be slightly different in each case.

For example, in sequential designs, leakage that tends to charge the node voltage V01 up will not be fatal to the operation of the circuit. Leakage resulting in discharging of the node voltage V01 can on the other hand result in degradation or failure of circuit function. In sensing circuits operated simultaneously for all slices, too much leakage either into the node or out of it can be fatal to the circuit function.

A modification is to force the leakage current at all times to be in whichever of the two possible directions that happens to be more favorable, e.g. such that the node is always charged up by the leakage current(s) (particularly applicable to gate driver designs with sequential threshold voltage sensing) or to minimize the leakage and reduce any unwanted movement in the node voltage (applicable to both types of gate driver designs).

The solution presented below can in fact be applied generally to any circuit where charge is stored on a capacitive node and where a leakage path (or paths) exists.

FIG. 12 shows a basic circuit for detecting leakage current.

A transistor (such as the transistor implementing switch S2 which is used to charge the node to the high voltage rail) is replaced by two series transistors, shown as T_{AUX1} and T_{AUX2} in FIG. 12. Their gates are connected together so that they are controlled by a common control signal, but the junction (called node X) between their connected source and drain is connected to a further control line, to which a control voltage is applied, named V_{MITIGATE} in FIG. 12.

In the off state, the gate voltage V_{OFF} and the supply voltage V_{S} must be arranged such that the gate is not above the supply voltage by more than the threshold voltage of transistor T_{AUX2}.

The effect of the voltage V_{MITIGATE} is that the resulting drain-source voltage across T_{AUX1} forces the leakage current to be in the preferred direction.

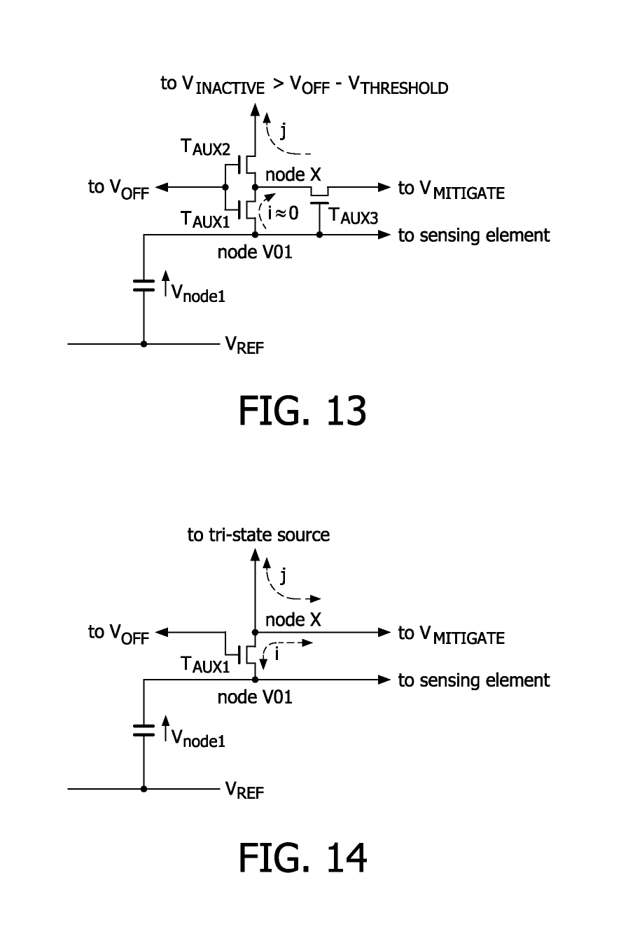

When the objective is to minimize the leakage then node X can be maintained at a potential close to that of NODE1 as shown in FIG. 13. The circuit of FIG. 13 uses a third transistor T_{AUX3} to introduce a threshold voltage drop across the transistor T_{AUX1} thereby forcing the leakage current to a low value.

Node X is charged up by T_{AUX3} to a potential V_{node1}−V_{TH}(T_{AUX3}). V_{MITIGAT}E must be greater than V_{node1}+V_{TH}(T_{AUX3}) whilst V_{INACTIVE} must be less than V_{node1}. In addition, it may be necessary to make T_{AUX3} sufficiently small and T_{AUX2} sufficiently large relative to T_{AUX3} that the leakage current through T_{AUX3} never exceeds the leakage current through T_{AUX1} by a sufficiently large margin to prevent correct operation of the circuit in the range of voltages of interest. The stressing of T_{AUX3} is minimal and it will therefore age only negligibly.

In both examples above, node X is rendered high impedance by turning off T_{AUX1} and T_{AUX}2 so that node X can be maintained at a desired potential. The same could be accomplished in principle without the second transistor T_{AUX2} if node X is directly connected to a tri-state source, capable of switching to a high impedance state. FIG. 14 shows an example of such an arrangement.

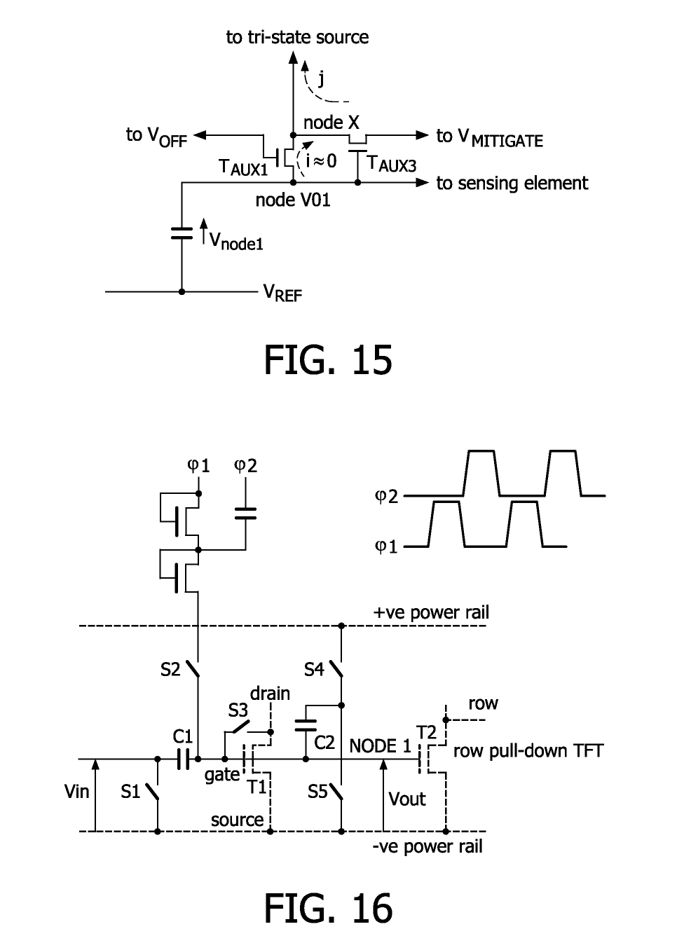

FIG. 15 shows the use of an additional transistor (as in the example of FIG. 11) applied to the circuit of FIG. 14.

In the case of minimizing leakage, the characteristics of the high impedance state will be important since the operation of the circuit depends on the existence of a leakage current out of node X The high impedance source must be able to sink some leakage current from T_{AUX3}. In other words, the high impedance source must not be a perfect open circuit, otherwise node X could continue charging until it reaches V_{MITIGATE}.

The circuits above can implement the switch S2 in the shift register circuits above, and can be used to implement simultaneous threshold voltage sensing or sequential sensing.

As explained above, the range over which Vₜ is measurable (or the range over which leakage currents can be compensated), and therefore the operating life of the circuit, is dependent on the maximum available power supply in the circuit. In the above circuits, the maximum threshold voltage that can be stored is somewhat below power supply voltage as a result of the voltage drop across the transistor used to charge NODE1 to the high rail voltage.

It would be beneficial to extend the available power supply, but it may not be possible or desirable to introduce additional supply rails at a higher potential or to operate the entire circuit at a higher voltage.

A required extended voltage range can be created with a simple charge pump. The only time when a significant amount of current is required from such an extended voltage source is at power-up, an event that is comparatively rare and equates to low duty operation. During the rest of the operation such an extended voltage source is loaded with leakage currents only. In a preferred modification, simple charge-pump circuits can be formed with diode-connected amorphous silicon TFTs. The circuits either operate at very low duty under load conditions, or continuously (high-duty) with no significant load in order to achieve long operating life.

FIG. 16 shows a modification to FIG. 2 in which the transistor which implements switch S2 is connected to the output of a charge pump circuit. This extends the range in which the threshold voltage can be sensed and stored. The voltage range is now a multiple of the clock voltage that operates the charge pump(s). One charge pump per row driver stage can be used, or alternatively one or more larger centralized charge pumps can be used. The clocks operating the charge pump can be the same as the clocks operating the row driver output stages (i.e. no additional clocks are needed).

A simple implementation is shown in FIG. 16, in which the charge pump circuit comprises two diode-connected transistors in series between a first control line and the circuit input. A second control line is connected to one end of a pump capacitor, with the other end connected to the junction between the diode connected transistors. The control signals are complementary.

At power up, the charge pump is loaded for the amount of time that it takes to charge up NODE1. This mode of operation happens infrequently and therefore the TFTs forming the charge pump do not age unduly. During normal operation NODE1 is already at or near its normal operating potential (i.e. does not need further charging), therefore the load on the charge pump can be kept to a minimum—just enough to counteract any leakage from NODE1. This can alternatively be accomplished by means of a second charge pump that supplies NODE1 via a high impedance path such as a TFT in its off state.

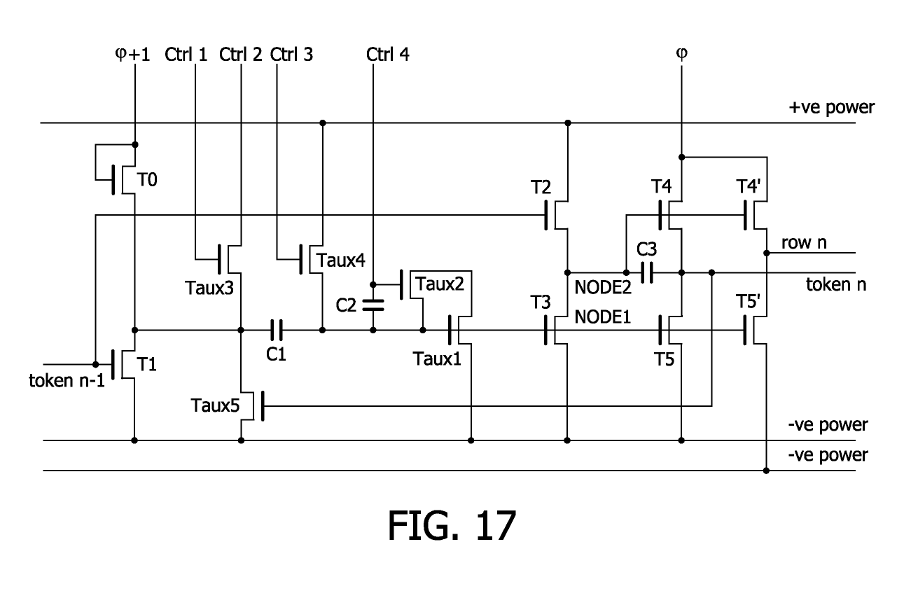

FIG. 17 shows a further embodiment to illustrate some further possible modifications.

In the circuit of FIG. 17, the transistors labeled T0, T1, T2, T3, T4, T5, T4′, T5′ form the basic shift register, corresponding to that shown in FIG. 6, but with two output stages. The output is split into a “row” output from one output stage and a “token” output from the other output stage, in order to isolate noise coming in from the row electrodes of the display active matrix from the shift register. As shown, the token output is used to control the timing of the other stages, and the output stage used to drive the row is used only for providing the row output signal.

The row is also driven from separate negative supply rails, to reduce spurious effects from power supply loading.

In the example of FIG. 17, the threshold voltage sensing function is implemented with a dedicated transistor Tₐᵤₓ₁ (not T3 as in the previous examples). Thus, some examples using existing transistors of the shift register stage to provide a transistor which replicates the ageing of the transistor to be compensated, or else a dedicated transistor can be provided for this purpose.

The switch S2 for charging the output side of the capacitor is implemented by Tₐᵤₓ₄, and the switch S3 for diode-connecting the transistor being sampled is implemented by Tₐᵤₓ₂.

Tₐᵤₓ₃ performs the function of switch S1 of bringing the input side of the capacitor to the low voltage rail and also the reset function after threshold voltage sensing to return the row slice to idling condition.

Tₐᵤₓ₅ is added to mitigate the effect of parasitic gate-drain capacitances of T3, T5 and T5′.

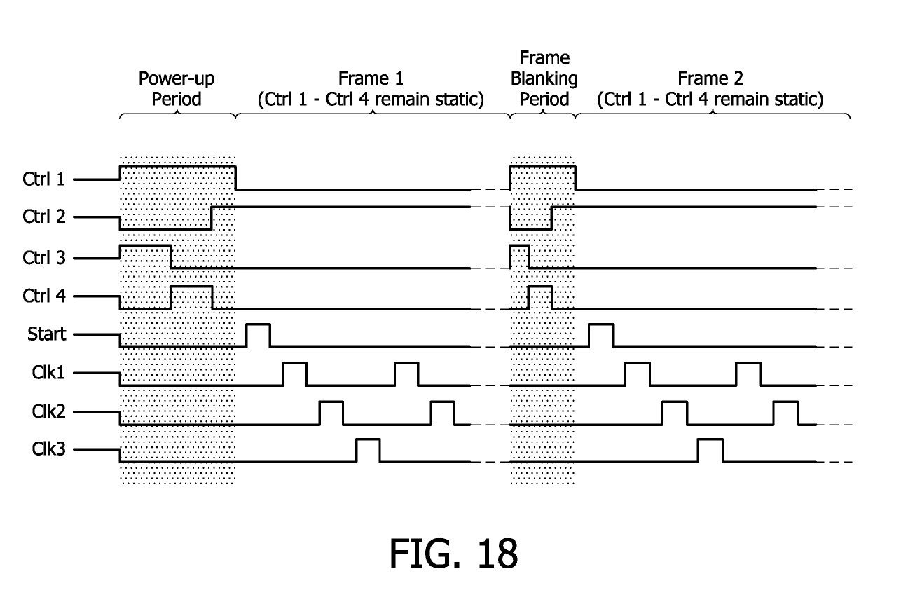

As shown in the timing diagram of FIG. 18, the threshold voltage sensing is carried out at power-up and in every frame blanking period. During power up, the signals Ctrl3 and Ctrl4 are extended in time to allow NODE1 to charge and discharge fully. During frame blanking Ctrl3 and Ctrl4 signals can be much shorter since NODE1 is already roughly at the right potential.

The circuit functions essentially in the same way as the previous examples. In particular, during the frame blanking periods:

Ctrl1 and Ctrl3 are brought high, with a low voltage on Ctrl2. This sets the voltage on each side of the capacitor C1.

Ctrl3 is then taken low and Ctrl4 is brought high. The output side of the capacitor C1 can then be discharged as it is no longer coupled to the high voltage rail. The replica transistor Tₐᵤₓ₁ is diode-connected and conducts until the threshold voltage is stored on C1.

Tₐᵤₓ₂ is then turned off, so that the replica transistor is no longer diode-connected, and the control line Ctrl2 is brought high. This provides the desired step change to the input of the capacitor C1 to give the desired compensated voltage to NODE1 to control the pull down transistors T5 and T5′ (and T3).

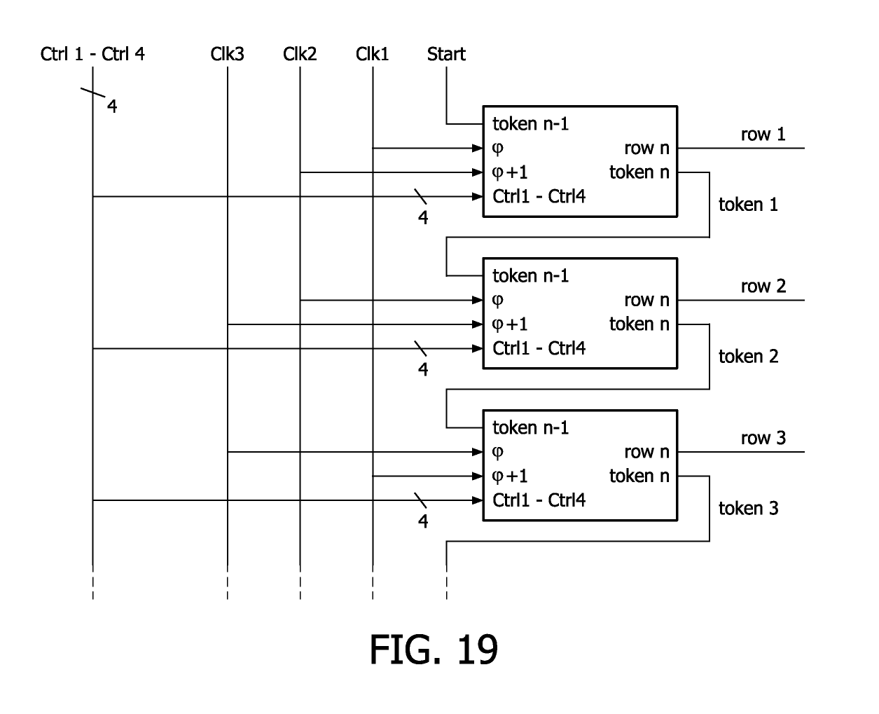

FIG. 19 shows how the different row slices are connected together, using the token output from one row slice as a timing control signal for the next row slice.

The invention is applicable to display/sensor array gate driver circuits using a-Si, e.g. EPLaR flexible E-Ink display. It may be applicable to other types of semiconductor materials e.g. polymer in which threshold voltage instability is problematic.

The invention could be applied together as a cost and/or space saving measure for active matrix displays such as LCD, OLED/PLED, E-Ink or any other display/sensor array technology that uses amorphous silicon or another type of semiconductor with threshold voltage instability. For example it could be suitable for mobile or PC monitor LCDs/OLEDs, potentially LCTV/OLEDTV screens and e-book displays.

In the examples above, the transistors are all n-type (as is preferred for an amorphous silicon implementation). However, the transistors may be p-type or the circuit may have a mixture of these. It is also conceivable for the circuit to have a normally-high output. In this case, the pull-up transistor will suffer the greater stress-induced degradation, and the compensation scheme of the invention can then be applied to the pull-up transistor.

For the n-type implementations shown, the top power rail is positive with respect to the negative power rail, but this can be reversed for p-type implementations.

The various examples above show a number of different possible implementations. It can be seen that for turn off of the pull-down transistor, the sampled threshold voltage can be altered in a number of ways, including:

a capacitive charge sharing can be introduced (using C2 and switches S4 and S5 as shown in FIG. 2, or using C2 and the control line Ctrl3 as shown in FIG. 6)

by sampling the threshold using a different voltage reference so that there is a voltage step change when a voltage rail is used as input (as in FIGS. 9 and 10).

In either case, a change to the sampled threshold voltage is introduced and this new voltage is capacitively coupled by the storage capacitor C1 to an input voltage, so as to provide the desired shift in the NODE1 voltage.

While the invention has been illustrated and described in detail in the drawings and foregoing description, such illustration and description are to be considered illustrative or exemplary and not restrictive; the invention is not limited to the disclosed embodiments. Variations to the disclosed embodiments can be understood and effected by those skilled in the art in practicing the claimed invention, from a study of the drawings, the disclosure, and the appended claims. In the claims, the word “comprising” does not exclude other elements, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

1. A shift register circuit comprising a plurality of stages, each stage being for providing an output signal to an output load and comprising a pull up transistor (40) for pulling the output signal up to a high voltage rail and a pull down transistor (42) for pulling the output signal down to a low voltage rail, wherein each stage comprises a circuit (S1,S2,S3,S4,S5,C1) for sampling the threshold voltage of at least one of the pull up and pull down transistors and for adding the sampled threshold voltage to a control voltage by capacitive coupling, to provide a threshold-voltage-compensated signal for controlling the gate of the at least one of the pull up and pull down transistors, wherein the circuit is adapted to apply a voltage step to the sampled threshold voltage for generating a turn-on signal, and is adapted to apply an opposite sign voltage step to the sampled threshold voltage, for generating a turn-off signal.

2. A circuit as claimed in claim 1, wherein the sampling circuit comprises a sampling capacitor (C1) in series between a control voltage input (Vᵢₙ) for the stage and the gate of the at least one (42) of the pull up and pull down transistors (40,42).

3. A circuit as claimed in claim 2, wherein the sampling circuit comprises a first switch (S1) for coupling one side of the sampling capacitor (C1) to a low voltage line and a second switch (S2) for coupling the other side of the sampling capacitor to a high voltage rail.

4. A circuit as claimed in claim 3, wherein the sampling circuit further comprises a charge pump circuit associated with the second switch (S2), for boosting the high voltage rail voltage.

5. A circuit as claimed in claim 3, wherein the sampling circuit comprises a third switch (S3) for shorting the gate and drain of the at least one of the pull up and pull down transistors or for shorting the gate and drain of a transistor (14) used to replicate the at least one (42) of the pull up and pull down transistors.

6. A circuit as claimed in claim 5, further comprising a capacitor (C2) connected between the control line for controlling the third switch (S3) and the other side of the sampling capacitor (C1).

7. A circuit as claimed in claim 1, wherein the low voltage line comprise a low voltage rail, and the sampling circuit comprises a fourth switch (S4) and a fifth switch (S5) connected in series between the power rails, with the junction between the fourth and fifth switches connected to one side of a capacitor (C2), the other side of the capacitor being connected to the gate of the at least (42) one of the pull up and pull down transistors (40,42).

8. A circuit as claimed in claim 5, wherein the first switch (S1) is connected between a reference power line (Vref) and the one side of the sampling capacitor (C1) such that the threshold voltage is sampled relative to the reference power line voltage (V_{ref}), and wherein a further switch (S4) is connected between the one side of the sampling capacitor (C1) and a low voltage rail.

9. A circuit as claimed in claim 1, further comprising leakage current control circuitry (Tₐᵤₓ₁, Tₐᵤₓ₂, Tₐᵤₓ₃) for controlling the direction of flow or magnitude of leakage current to or from the gate of the at least one of the pull up and pull down transistors, connected between the gate of the at least one of the pull up and pull down transistors and a power supply line.

10. A circuit as claimed in claim 9, wherein the leakage current control circuitry comprises two transistors (Tₐᵤₓ₁, Tₐᵤₓ₂) in series with connected gates and with a control voltage line (V_{MITIGATE}) to the series connection between the transistors.

11. A circuit as claimed in claim 10, wherein the leakage current control circuitry further comprises a third transistor (Tₐᵤₓ₃) with the gate and source terminals connected to the source and drain terminals of one of the two transistors (Tₐᵤₓ₁, Tₐᵤₓ₂).

12. A circuit as claimed in claim 9, wherein the leakage current control circuitry comprises a transistor (Tₐᵤₓ₁) connected between the gate of the at least one of the pull up and pull down transistors and the power supply line, wherein the power supply line comprises a tri-state power source, and the leakage current control circuitry further comprises a control voltage line (V_{MITIGATE}) for controlling the voltage applied to the transistor when the power supply is switched to a high impedance state.

13. A circuit as claimed in claim 12, wherein the leakage current control circuitry further comprises a second transistor (Tₐᵤₓ₃) with the gate and source terminals connected to the source and drain terminal of the transistor.

14. A circuit as claimed in claim 1, wherein the circuit for sampling the threshold voltage of at least one of the pull up and pull down transistors includes the at least one (42) of the pull up and pull down transistors (40,42).

15. A circuit as claimed in claim 1, wherein the circuit for sampling the threshold voltage of at least one of the pull up and pull down transistors includes a transistor (14) used to replicate the behavior of the at least one (42) of the pull up and pull down transistors (40,42).

16. A circuit as claimed in claim 1, wherein each stage comprises an input section (44,46,48) and an output section (40,42), wherein the output section comprises the pull up and pull down transistors, and a bootstrap capacitor (C3) between the gate of the pull up transistor (40) and the output.

17. A circuit as claimed in claim 16, wherein the input section of each stage comprises:
a first input section input (row n−1) connected to the output of the input section of a preceding stage; and
a transistor (48) for charging the first bootstrap capacitor and controlled by the first input (row n−1).

18. A circuit as claimed in claim 1, implemented using amorphous silicon technology.

19. An active matrix display device, comprising:
an array of active matrix display pixels;
row driver circuitry comprising a shift register circuit as claimed in claim 1.

20. An active matrix display device as claimed in claim 19, comprising an active matrix liquid crystal display device.

21. A method of generating multiple stage shift register circuit outputs for providing a signal to an output load, comprising, for each stage of the shift register circuit, generating an output signal by switching on a pull up transistor (40) to pull the output signal up to a high voltage rail or switching on a pull down transistor (42) to pull the output signal down to a low voltage rail, wherein the method further comprises:
sampling the threshold voltage of at least one (42) of the pull up and pull down transistors (40,42);
applying a voltage of a first polarity to the sampled threshold voltage for generating a turn-on signal for controlling the gate of the at least one (42) of the pull up and pull down transistors; and
applying a voltage of an opposite second polarity to the sampled threshold voltage, for generating a turn-off signal for controlling the gate of the at least one of the pull up and pull down transistors.
